(19) United States
(12) Patent Application Publication
(10) Pub. No.: US 2009/0009940 A1
(43) Pub. Date: Jan. 8, 2009

(54) DISPLAY HAVING A STORAGE SPACE FOR A REMOTE CONTROL

(75) Inventors: Guan-De Liou, Taipei City (TW); Chia-Pine Huang, Keelung City (TW); Li-Li Lai, Taipei City (TW); Stephen Tsai, Taipei County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HANNSPREE, INC., Taipei City (TW)

(21) Appl. No.: 11/949,804

(22) Filed: Dec. 4, 2007

(30) Foreign Application Priority Data
Jul. 2, 2007 (TW) 96123956

(51) Int. Cl. H04N 5/64; H05K 5/02

(52) U.S. Cl. 361/681; 211/26.1

(57) ABSTRACT

A display comprises a main body, a storage space, and a remote control. The main body has a first surface and a second surface. The storage space is formed on the second surface. The remote control is removeably disposed in the storage space. The display further comprises a supporting frame. The supporting frame is rotatably attached to the main body. The supporting frame is secured into the storage space when situated at a first position, and the supporting frame is rotated out of the storage space when situated at a second position. The remote control is removeably disposed in the supporting frame.

### BACKGROUND OF THE INVENTION

1. Field of the Invention

The invention relates to a display having a storage space for a remote control. The remote control for the display is designed with a specific shape, and a main body of the display has a storage space which can match to the shape of the remote control for accommodating the remote control which adds an united effect between the remote control and the main body.

2. Description of the Related Art

With the advancement of technology, quality of human life has been highly upgraded. Today, displays with light-weight and slim designs have replaced conventional CRT displays with bulky sizes. Portable displays have been welcomed by consumers and are becoming mainstream devices for people to enjoy visual entertainment gadget in the world.

In general, the main body of a conventional portable display and the remote control for the conventional portable display (hereinafter referred to as display) are designed as separate devices. As a result, a user usually does not put the remote control in a fixed position and therefore can not find it easily after he/she has put away the remote control for a period of time. Because keep on looking for the remote control, before watching a TV program will upset the users, a TV with easy RC locating design would definitely be more user-friendly. Meanwhile, the shape of remote controls for conventional displays is not stylish or appealing. Thus, a remote control design eliminate the above inconveniences would be good for common TV viewers.

### BRIEF SUMMARY OF THE INVENTION

The invention provides a display comprising a main body, a storage space, and a remote control. The main body has a first surface and a second surface. The storage space is formed on the second surface. The remote control is removeably disposed in the storage space.

The first surface may be a front of the display.

The second surface may be a back of the display.

The remote control is substantially rounded, cross-shaped, elliptic or polygonal.

A shape of the storage space substantially matches the shape of the remote control.

A notch is formed on the second surface and communicates with the storage space.

The remote control has a notch for convenient separation.

The remote control is tightly fitted into the storage space.

The main body has a fastening element on the second surface securing the remote control in the storage space.

The main body has a rotary fixing element on the second surface securing the remote control in the storage space.

A depth of the storage space substantially matches a thickness of the remote control.

The invention provides another display comprising a main body, a storage space, a supporting frame, and a remote control. The main body has a first surface and a second surface. The storage space is formed on the second surface. The supporting frame is rotatably attached to the second surface of the main body, wherein the supporting frame is accommodated into the storage space when situated at a first position, and the supporting frame is rotated out of the storage space when situated at a second position. The remote control is removeably disposed in the supporting frame.

The first surface may be a front of the display.

The second surface may be a back of the display.

The remote control has a third surface, a fourth surface and an exterior rim connecting to the third surface and the fourth surface.

The supporting frame comprises an interior rim surrounding the exterior rim of the remote control.

The supporting frame comprises a bottom flange partially covering the third surface of the remote control.

The supporting frame comprises a solid bottom and a rim. The rim surrounds the solid bottom.

The solid bottom has a hole for the wires.

The remote control is substantially rounded, cross-shaped, elliptic or polygonal.

A shape of the storage space substantially matches the shape of the remote control.

The supporting frame has a notch.

The remote control has a notch.

The remote control is tightly fitted into the storage space.

The main body has a fastening element on the second surface securing the remote control in the storage space.

The main body has a rotary fixing element on the second surface securing the remote control in the storage space.

A depth of the storage space can substantially fits a thickness set on the remote control.

For the above descriptions, the main body and the remote control of the display are combined together to form an integral appearance. Specifically, a shape of the storage space of the main body is similar to the remote control. After the user has finished using the remote control, the remote control is placed back into the storage space of the main body. Thus, the remote control will always be located and found at a specific location, relieving users of emotional distress and inconvenience. In addition, the shape of the remote control of the invention is varied with appeal and style and the holding method is improved.

### BRIEF DESCRIPTION OF THE DRAWINGS

The invention can be more fully understood by reading the subsequent detailed description and examples with references made to the accompanying drawings, wherein:

FIG. 1 is a schematic view of a display in accordance with the first embodiment of the invention.

FIG. 2 is a schematic view of a display in accordance with the second embodiment of the invention.

FIG. 3 is a schematic view of a display in accordance with the third embodiment of the invention.

FIG. 4 is a schematic view of a supporting frame situated at the first position with a bottom flange of a display in accordance with the fourth embodiment of the invention.

FIG. 5 is a schematic view of a supporting frame situated at the second position with a bottom flange of a display in accordance with the fourth embodiment of the invention.

FIG. 6 is a schematic view of a back of a supporting frame with a bottom flange of a display.

FIG. 7 is a schematic view of a supporting frame situated at the second position with a solid bottom of a display in accordance with the fifth embodiment of the invention.

FIG. 8 is a schematic view of a back of a supporting frame with a solid bottom of a display.

FIG. 9 is a schematic view of a hollow supporting frame situated at the second position of a display in accordance with the sixth embodiment of the invention.

FIG. 10 is a schematic view of a hollow supporting frame of a display.

### DETAILED DESCRIPTION OF THE INVENTION

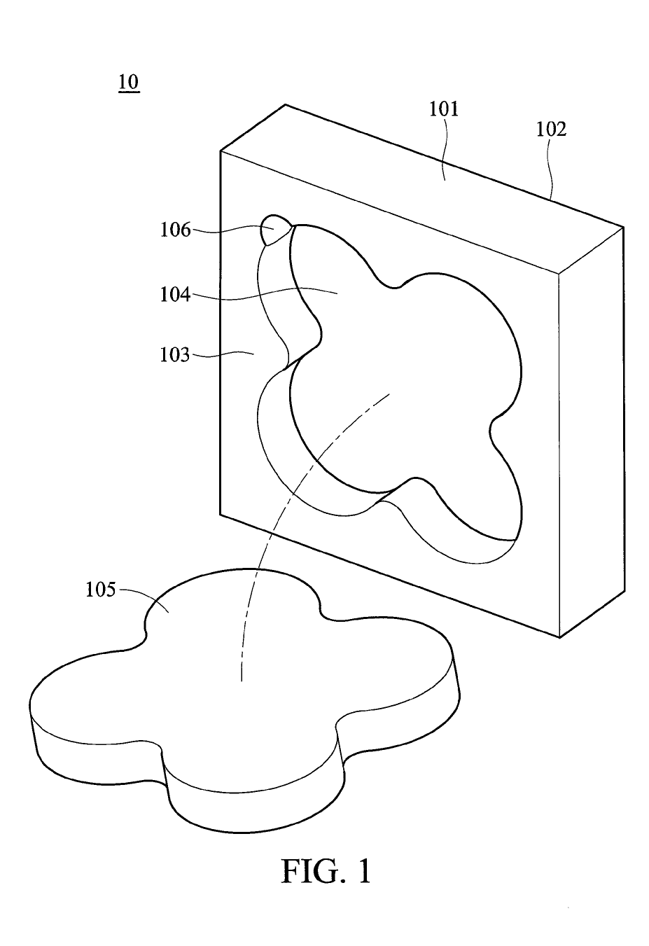

Referring to FIG. 1, a display of the first embodiment of the invention is shown. The display 10 comprises a main body 101, a storage space 104, and a remote control 105, described in detail in the following:

The main body 101 has a first surface 102 and a second surface 103, wherein the first surface 102 is a front of the display and the second surface 103 is a back of the display.

The storage space 104 is formed on the second surface 103. The remote control 105 is removeably disposed in the storage space 104. A shape of the storage space 104 substantially matches the shape of the remote control 105, and a depth of the storage space 104 substantially matches the thickness of the remote control 105. For the design of the remote control 105, the shape may vary dependent upon requirements (e.g. round, cross-shaped, elliptic or polygonal etc.).

The remote control 105 is tightly fitted into the storage space 104. Therefore, the remote control 105 can be firmly secured in the storage space 104. The tight fit between the storage space 104 and the remote control 105 prevents the remote control 105 from falling out and being damaged.

A notch 106 is formed on the second surface 103 of the main body 101 and borders with the storage space 104. The notch 106 facilitates the user when removing the remote control 105 from the storage space 104.

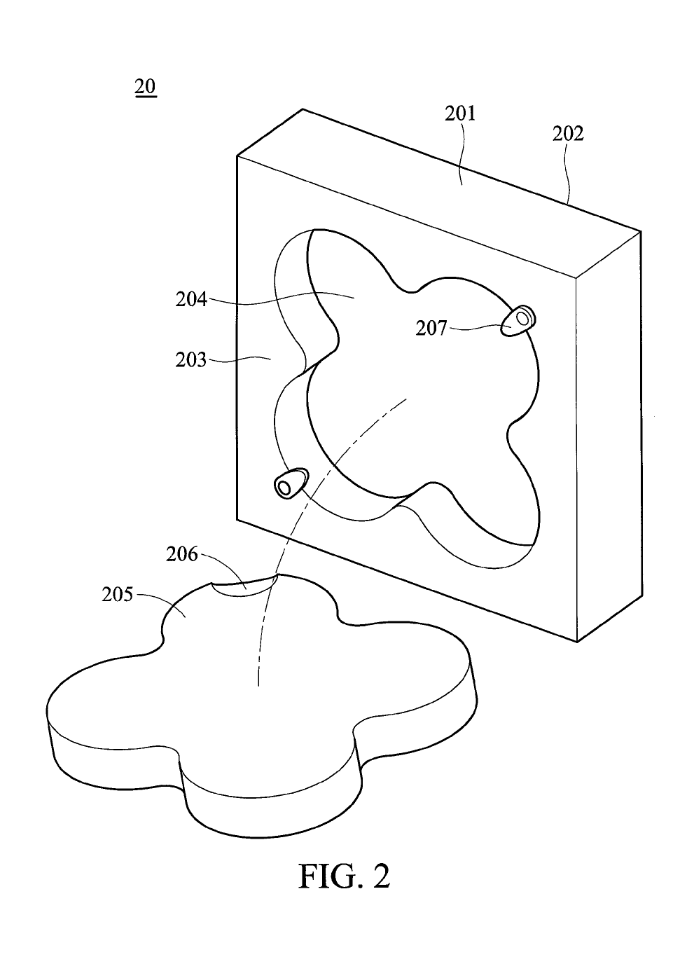

Referring to FIG. 2, a display of the second embodiment of the invention is shown. The display 20 comprises a main body 201, a storage space 204, and a remote control 205, described in detail in the following.

The main body 201 has a first surface 202 and a second surface 203, wherein the first surface 202 is a front of the display and the second surface 203 is a back of the display.

The storage space 204 is formed on the second surface 203. The remote control 205 is removeably disposed in the storage space 204. A shape of the storage space 204 substantially matches the shape of the remote control 205, and the depth of the storage space 204 substantially matches the thickness of the remote control 205. For the design of the remote control 205, the shape may vary dependent upon requirements (e.g. round, cross-shaped, elliptic or polygonal etc.).

The remote control 205 can be secured in the storage space 204 by a rotary fixing element 207 situated between the storage space 204 and the remote control 205. The rotary fixing element 207 is disposed on the second surface 203 of the main body 201 to prevent the remote control 205 from falling out and being damaged.

A notch 206 is formed on the remote control 205. The notch 206 facilitates the user when removing the remote control 205 from the storage space 204. The function of the notch 206 of the second embodiment and the notch 106 of the first embodiment is the same.

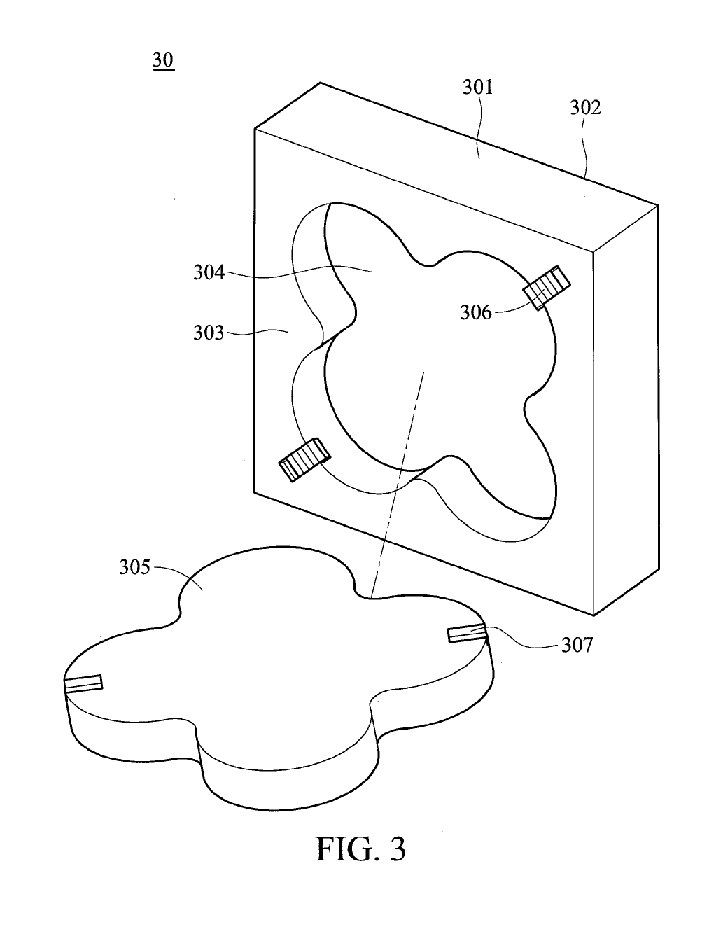

Referring to FIG. 3, a display of the third embodiment of the invention is shown. The display 30 comprises a main body 301, a storage space 304, and a remote control 305, described in detail in the following.

The main body 301 has a first surface 302 and a second surface 303, wherein the first surface 302 is a front of the display and the second surface 303 is a back of the display.

The storage space 304 is formed on the second surface 303. The remote control 305 is removeably disposed in the storage space 304. A shape of the storage space 304 substantially matches the shape of the remote control 305, and the depth of the storage space 304 substantially matches the thickness of the remote control 305. For the design of the remote control 305, the shape may vary dependent upon requirements (e.g. round, cross-shaped, elliptic or polygonal etc.).

The remote control 305 is secured in the storage space 304 by a fastening element 306 and a groove 307. The fastening element 306 is movably disposed on the second surface 303 of the main body 301 and the groove 307 disposed on the remote control 305 to prevent the remote control 305 from falling out and being damaged.

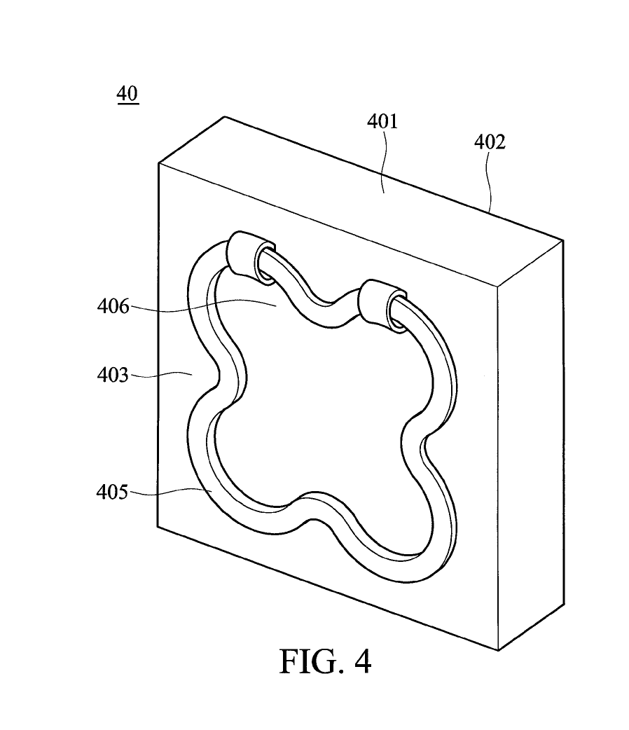

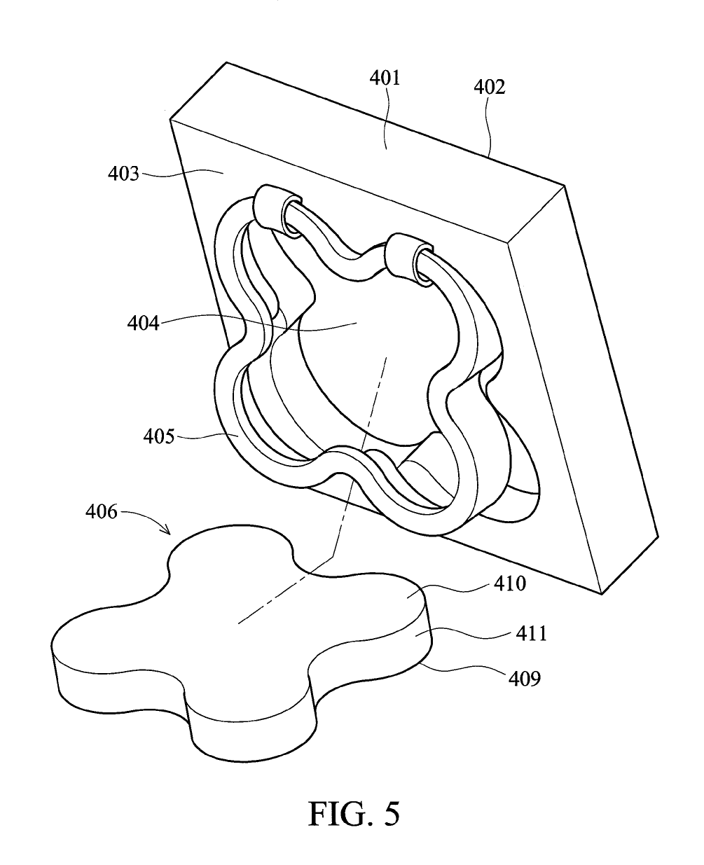

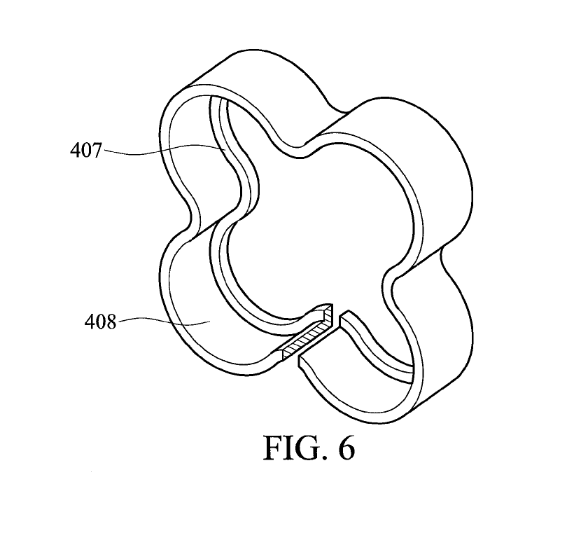

Referring to FIG. 4, a schematic view of a supporting frame situated at the first position in accordance with the fourth embodiment of the invention is shown. Referring to FIG. 5, a schematic view of a supporting frame situated at the second position in accordance with the fourth embodiment of the invention is shown. Referring to FIG. 6, a back of a supporting frame (wherein a section of the bottom of the supporting frame is removed for illustrative purposes) is shown. In FIG. 4, FIG. 5 and FIG. 6, the display 40 of the invention comprises a main body 401, a storage space 404, a supporting frame 405 and a remote control 406, described in detail in the following.

The main body 401 has a first surface 402 and a second surface 403, wherein the first surface 402 is a front of the display and the second surface 403 is a back of the display.

The remote control 406 has a third surface 409, a fourth surface 410, and an exterior rim 411, wherein the third surface 409 is a front of the remote control, the fourth surface 410 is a back of the remote control, and the exterior rim 411 connects the third surface 409 and the fourth surface 410.

The support frame 405 is rotatably attached to the main body 401 and comprises a bottom flange 407 and an interior rim 408. The interior rim 408 surrounds the exterior rim 411 of the remote control and the bottom flange 407 protrudes inwardly from the bottom of the interior rim 408. When the remote control 406 is situated in the supporting frame 405, the bottom flange 407 obstructs the remote control 406 and partly covers the third surface 409 of the remote control 406. The remote control 406 is removeably disposed in the supporting frame 405, and the supporting frame 405 is used to secure the remote control 406, preventing the remote control 406 from falling out. The supporting frame 405 is secured into the storage space 404 when situated at a first position (as shown in FIG. 4), and the supporting frame 405 is rotated out of the storage space 404 when situated at a second position (as shown in FIG. 5). The supporting frame 405 also operates as a support for the display 40 and allows the user to adjust the viewing angle of the display 40.

The storage space 404 is formed on the second surface 403. A shape of the storage space 404 substantially matches the shape of the remote control 406, and the depth of the storage space 404 substantially matches the thickness of the remote control 406. For the design of the remote control 406, the shape may vary dependent upon requirements (e.g. round, cross-shaped, elliptic or polygonal etc.).

The method of fixing the remote control 406 to the supporting frame 405 in the fourth embodiment is similar to the method described for the first embodiment, the second embodiment and the third embodiment. The remote control 406 is tightly fitted into the supporting frame 405. In addition, a fastening element or a rotary fixing element is provided on the supporting frame to secure the remote control 406. Thus, the remote control does not fall out of the supporting frame and become damaged. Meanwhile, the method of removing the remote control 406 in the fourth embodiment is similar to the method described for the first embodiment and the second embodiment. A notch can be disposed on the remote control or supporting frame to assist the user in retrieving the remote control easily and conveniently.

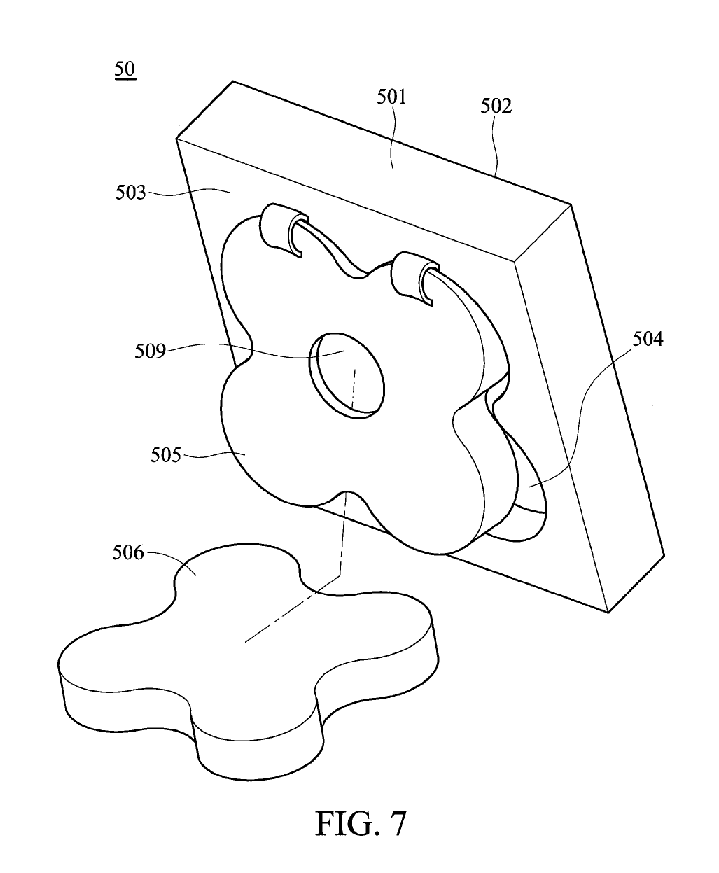

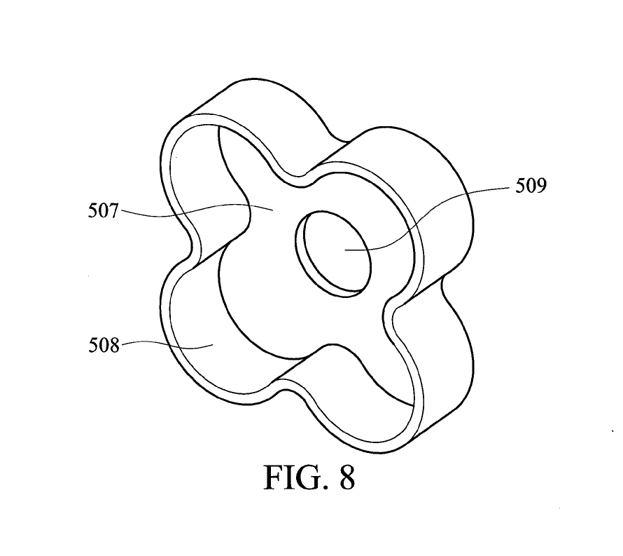

Referring to FIG. 7, a schematic view of a supporting frame situated at the second position in accordance with the fifth embodiment of the invention is shown. Referring to FIG. 8, a back of the supporting frame is shown. In FIG. 7 and FIG. 8, the display 50 of the invention comprises a main body 501, a storage space 504, a supporting frame 505 and a remote control 506, described in detail in the following:

The main body 501 has a first surface 502 and a second surface 503, wherein the first surface 502 is a front of the display and the second surface 503 is a back of the display.

The supporting frame 505 is rotatably attached to the main body 501 and comprises a solid bottom 507 and an interior rim 508. The interior rim 508 surrounds the solid bottom 507 and the remote control 506 is removeably disposed in the supporting frame 505. The supporting frame 505 is used to secure the remote control 506 to prevent the remote control 506 from falling out. The fifth embodiment differs from the fourth embodiment in that the bottom 507 of the supporting frame 505 is solid and a wire hole 509 is provided in the center of the solid bottom 507. Wires of the display can be connected to power terminals by passing through the wire hole 509. Thus, when using the display, the wires are not disorderly and unsystematic. Similar to that of the fourth embodiment, the supporting frame 505 is secured in the storage space 504 when situated at a first position (not shown), and the supporting frame 505 is rotated out of the storage space 504 when situated at a second position (as shown in FIG. 7). The supporting frame 505 also operates as a support for the display 50 and allows the user to adjust the viewing angle of the display 50.

The storage space 504 is formed on the second surface 503. A shape of the storage space 504 substantially matches the shape of the remote control 506, and the depth of the storage space 504 substantially matches the thickness of the remote control 506. For the design of the remote control 506, the shape may vary dependent upon requirements (e.g. round, cross-shaped, elliptic or polygonal etc.).

The method of securing the remote control 506 to the supporting frame 505 in the fifth embodiment is similar to in the method described for the first embodiment, the second embodiment, the third embodiment and the fourth embodiment. The remote control 506 is tightly fitted into the supporting frame 505. In addition, a fastening element or a rotary fixing element is provided on the supporting frame to secure the remote control 506. Thus, the remote control does not fall out of the supporting frame and become damaged. Meanwhile, the method of removing the remote control 506 in the fifth embodiment is similar to the method described for the first embodiment and the second embodiment. A notch can be disposed on the remote control or supporting frame to assist the user in retrieving the remote control easily and conveniently.

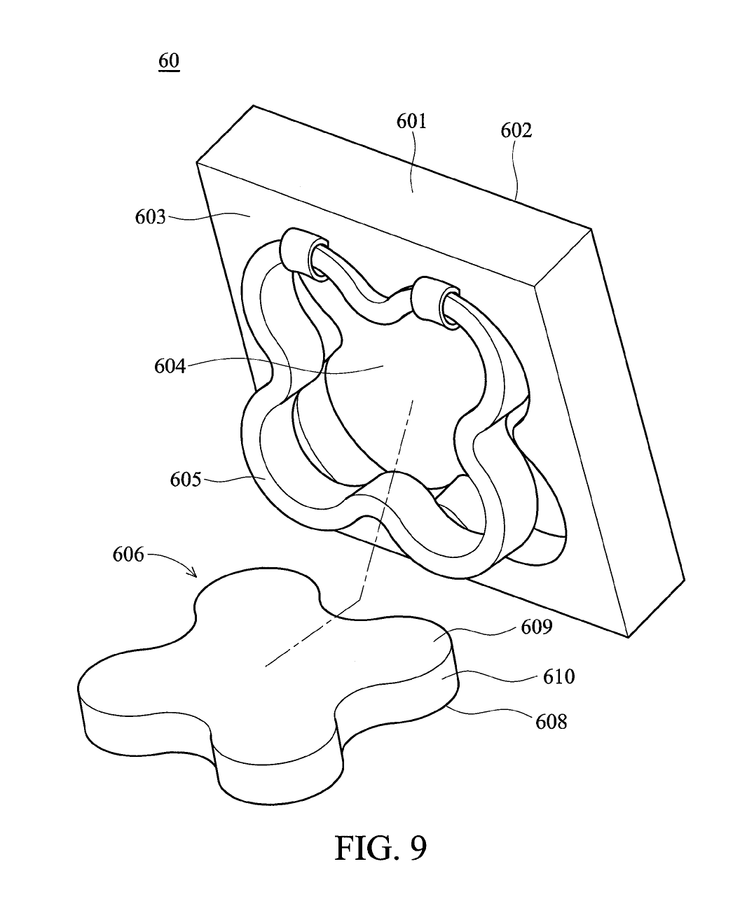

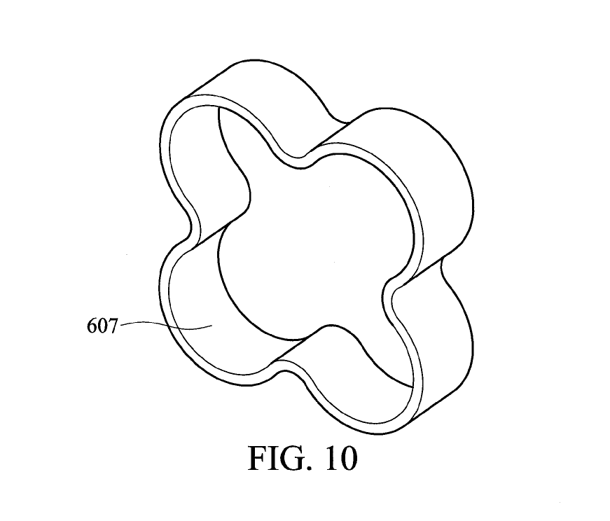

Referring to FIG. 9, a schematic view of a hollow supporting frame situated at the second position in accordance with the sixth embodiment of the invention and FIG. 10, a schematic view of a hollow supporting frame of a display are shown. In FIG. 9 and FIG. 10, the display 60 of the invention comprises a main body 601, a storage space 604, a supporting frame 605 and a remote control 606, described in detail in the following:

The main body 601 has a first surface 602 and a second surface 603, wherein the first surface 602 is a front of the display and the second surface 603 is a back of the display.

The remote control 606 has a third surface 608, a fourth surface 609, and an exterior rim 610, wherein the third surface 608 is a front of the remote control, the fourth surface 609 is a back of the remote control, and the exterior rim 610 connects the third surface 608 and the fourth surface 609.

The hollow support frame 605 is rotatably attached to the main body 601 and only comprises a rim 607. The rim 607 surrounds the remote control 606. The remote control 606 is removeably disposed in the supporting frame 605, and the supporting frame 605 is used to secure the remote control 606 to prevent the remote control 606 from falling out. The supporting frame 605 is secured into the storage space 604 when situated at a first position, and the supporting frame 605 is rotated out of the storage space 604 when situated at a second position (as shown in FIG. 9). The supporting frame 605 also operates as a support for the display 60 and allows the user to adjust the viewing angle of the display 60.

The storage space 604 is formed on the second surface 603. A shape of the storage space 604 substantially matches the shape of the remote control 606, and the depth of the storage space 604 substantially matches the thickness of the remote control 606. For the design of the remote control 606, the shape may vary dependent upon requirements (e.g. round, cross-shaped, elliptic or polygonal etc.).

The method of securing the remote control 606 to the supporting frame 605 in the sixth embodiment is similar to the method described in the first embodiment, the second embodiment, the third embodiment, the fourth embodiment and the fifth embodiment. The remote control 606 is tightly fitted into the supporting frame 605. In addition, a fastening element or a rotary fixing element is provided on the supporting frame to secure the remote control 606. Thus, the remote control does not fall out of the supporting frame and become damaged. In addition, the method of removing the remote control 606 in the sixth embodiment is similar to the method described in the first embodiment and the second embodiment. A notch can be disposed on the remote control or supporting frame to assist the user in retrieving the remote control easily and conveniently.

For a conventional display, the main body and the remote control are generally designed by as separate devices. Without a designated location for the remote control, the remote control is often misplaced and the user must search for the remote control after each period of time has lapsed. Additionally, the main design of the conventional display, in general, emphasizes functional demands, rather than aesthetic.

Furthermore, because the main body and the remote control are generally separate devices, additional space is required to be allocated for the remote control when packaging for shipment, thus increasing volume and packaging and shipment costs.

The main body and the remote control of the display of the invention are combined to conceal the remote control. A shape of the storage space of the main body is similar to that of the remote control. After the user has finished using the remote control, the remote control is placed back into the storage space of the main body. Thus, the remote control will always be located and found at a specific location, relieving users of emotional distress and inconvenience.

The remote control of the invention can have various functional and aesthetic shapes, surpassing the conventional remote controls in appearance and originality to attract consumers. Because the remote control of the invention can improve upon function and appearance, the remote control is aesthetic and practicable.

The fourth embodiment and the fifth embodiment of the display of the invention have supporting frames. The supporting frame can support the display in the operational state and secure the remote control during a non-operational state. As such, the remote control will not fall out and become damaged. Meanwhile, the wire hole can assist to maintain the order of the wires of the display so that the wires are not disorderly and unsystematic.

The supporting frame of the sixth embodiment of the display of the invention is hollow type. This allows the user to retrieve the remote control conveniently via the hollow supporting frame. Specifically, the user directly and conveniently retrieves and places back the remote control via the supporting frame.

The storage space of the display of the invention solves the problem of users misplacing the remote control. The remote control can have various shapes to function well, while still offering aesthetic design. The supporting frame and wire hole can assist the display to efficiently function in an operational or non-operational state. As for device packaging, due to the combination of the main body and the remote control, the invention can decrease volume and packaging and shipment costs.

The added storage space and supporting frame does not affect the functional abilities of the display. On the contrary, it increases the display function, improves display appearance, and expands upon convenience of use.

While the invention has been described by way of example and in terms of preferred embodiment, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A display comprising:
a main body having a first surface and a second surface;
a storage space formed on the second surface; and
a remote control removeably disposed in the storage space.

2. The display as claimed in claim 1, wherein the first surface is a front of the display and the second surface is a back of the display.

3. The display as claimed in claim 1, wherein the shape of the storage space substantially matches the shape of the remote control.

4. The display as claimed in claim 1, wherein a notch is formed on the second surface and borders with the storage space.

5. The display as claimed in claim 1, wherein the remote control has a notch.

6. The display as claimed in claim 1, wherein the remote control is tightly fitted into the storage space.

7. The display as claimed in claim 1, wherein the main body further has a fastening element on the second surface securing the remote control in the storage space.

8. The display as claimed in claim 1, wherein the main body further has a rotary fixing element on the second surface securing the remote control in the storage space.

9. A display comprising:
a main body having a first surface and a second surface;
a storage space formed on the second surface;
a supporting frame rotatably attached to the second surface of the main body, wherein the supporting frame is secured into the storage space when situated at a first position, and the supporting frame is rotated out of the storage space when situated at a second position; and
a remote control removeably disposed in the supporting frame.

10. The display as claimed in claim 9, wherein the first surface is a front of the display and the second surface is a back of the display.

11. The display as claimed in claim 9, wherein the remote control has a third surface, a fourth surface and an exterior rim connecting to the third surface and the fourth surface.

12. The display as claimed in claim 11, wherein the third surface is a front of the remote control and the fourth surface is a back of the remote control.

13. The display as claimed in claim 11, wherein the supporting frame comprises a interior rim surrounding the exterior rim of the remote control.

14. The display as claimed in claim 12, wherein the supporting frame comprises a bottom flange partially covering the third surface of the remote control.

15. The display as claimed in claim 9, wherein the supporting frame comprises:
a solid bottom; and
a rim surrounding the solid bottom.

16. The display as claimed in claim 15, wherein the solid bottom has a wire hole.

17. The display as claimed in claim 9, wherein the shape of the storage space substantially matches the shape of the remote control.

18. The display as claimed in claim 9, wherein the supporting frame has a notch.

19. The display as claimed in claim 9, wherein the remote control has a notch.

20. The display as claimed in claim 9, wherein the remote control is tightly fitted into the storage space.

21. The display as claimed in claim 9, wherein the main body further has a fastening element on the second surface securing the remote control in the storage space.

22. The display as claimed in claim 9, wherein the main body further has a rotary fixing element on the second surface securing the remote control in the storage space.
